(19) United States
(12) Patent Application Publication
(10) Pub. No.: US 2015/0027757 A1
(43) Pub. Date: Jan. 29, 2015

(54) PCB HAVING GLASS CORE

(71) Applicant: SAMSUNG ELECTRO-MECHANICS CO., LTD., Suwon (KR)

(72) Inventors: Yee Na SHIN, Suwon (KR); Seung Eun Lee, Sungnam (KR)

(73) Assignee: SAMSUNG ELECTRO-MECHANICS CO., LTD., Suwon (KR)

(21) Appl. No.: 14/074,372

(22) Filed: Nov. 7, 2013

(30) Foreign Application Priority Data
Jul. 29, 2013 (KR) 10-2013-0089496

(51) Int. Cl. H05K 1/03; H05K 1/02

(52) U.S. Cl. CPC H05K 1/0306; H05K 1/0271
USPC 174/255

(57) ABSTRACT

Disclosed herein is a printed circuit board (PCB) including a glass core for maintaining sufficient rigidity while maintaining a thin thickness to minimize warpage. The PCB includes a glass core having upper and lower surfaces in which pattern formation grooves and through via holes are formed, a plating layer filled in the pattern formation groves and the through via holes, insulating layers stacked on the upper and lower surfaces of the glass core, and solder resist layers formed on the insulating layers via coating.

### CROSS REFERENCE(S) TO RELATED APPLICATIONS

This application claims the benefit under 35 U.S.C. Section 119 of Korean Patent Application Serial No. 10-2013-0089496, entitled “PCB Having Glass Core” filed on Jul. 29, 2013, which is hereby incorporated by reference in its entirety into this application.

### BACKGROUND OF THE INVENTION

1. Technical Field

The present invention relates to a printed circuit board (PCB) including a glass core, and more particularly, to a PCB including a glass core for maintaining sufficient rigidity while maintaining a thin thickness to minimize warpage.

2. Description of the Related Art

Recently, to satisfy lightweight, miniaturized, high-speed, multi-functional, and high performance trends of electronic products, a need for high integration has been increased.

For high integration, the thickness of an electronic circuit board needs to be reduced. To this end, the thickness of a core as a base of the electronic circuit board needs to be absolutely reduced.

Currently, a process of manufacturing a printed circuit board (PCB) includes forming a circuit pattern on a core layer using a core layer to which a copper foil is attached and stacking layers formed of resin above and below the core layer.

The circuit pattern of the core may be formed by positioning a mask and then performing etching along a predesigned pattern.

In this case, layers of the core are electrically connected by forming a via hole using a CO₂ drill or mechanical drill and forming a plating layer in the via hole for connection between layers.

In the PCB, a wiring pitch needs to be reduced for high integration and high performance. To this end, a glass fiber obtained by changing the physical properties of a conventional core material and precipitating resin is used.

However, when the thickness of a core layer of a conventional PCB is reduced, many problems arise during manufacturing processes of the PCB. In particular, when an electronic device is mounted on the completed PCB, warpage may occur due to stress between the electronic device and the PCB.

### RELATED ART DOCUMENT

### Patent Document

### (Patent Document 1) Cited Document: Korean Patent Laid-Open Publication No. 2000-0036168

### SUMMARY OF THE INVENTION

An object of the present invention is to provide a printed circuit board (PCB) including a glass core so as to prevent warpage of a substrate using the glass core.

Another object of the present invention is to provide a PCB including a glass core that reduces a total thickness as well as ensures electrical stability using the glass core.

According to an exemplary embodiment of the present invention, there is provided a printed circuit board (PCB) including a glass core having upper and lower surfaces in which pattern formation grooves and through via holes are formed, a plating layer filled in the pattern formation groves and the through via holes, insulating layers stacked on the upper and lower surfaces of the glass core, and solder resist layers formed on the insulating layers via coating.

The pattern formation grooves may each be formed to have a square shape. The pattern formation grooves may each be formed to have a circular or oval shape.

In this case, the pattern formation groove may include an inner diameter a2 of a central part, which is greater than an upper inner diameter a1.

The through via hole may be formed to have any one of an hourglass type, an over type, and an inverse-hourglass type.

The pattern formation groove may have a greater horizontal width than a vertical width using other chemicals other than hydrofluoric acid solution

According to another exemplary embodiment of the present invention, there is provided a PCB including a glass core including pattern formation grooves and through via holes and including a cavity for accommodating an electronic device therein, a plating layer filled in the pattern formation grooves and the through via holes, and a solder resist layer formed on an insulating layer via coating.

The pattern formation grooves may each be formed to have a square shape and may each be formed to have a circular or oval shape. In addition, the through via hole may be formed to have any one of an hourglass type, an over type, and an inverse-hourglass type. The pattern formation groove may have a greater horizontal width than a vertical width.

### BRIEF DESCRIPTION OF THE DRAWINGS

FIG. 1 is a cross-sectional view of a printed circuit board (PCB) including a glass core according to a first embodiment of the present invention.

FIG. 2 is a cross-sectional view of a PCB including a glass core according to a second embodiment of the present invention.

FIG. 3 is a partially enlarged view of a pattern part of FIG. 3. FIGS. 4A, 4B, and 4C are exemplary views of a through via of a PCB including a glass core according to an embodiment of the present invention.

### DESCRIPTION OF THE PREFERRED EMBODIMENTS

Hereinafter, exemplary embodiments will be described in detail with reference to the accompanying drawings so that they can be easily practiced by those skilled in the art to which the present invention pertains.

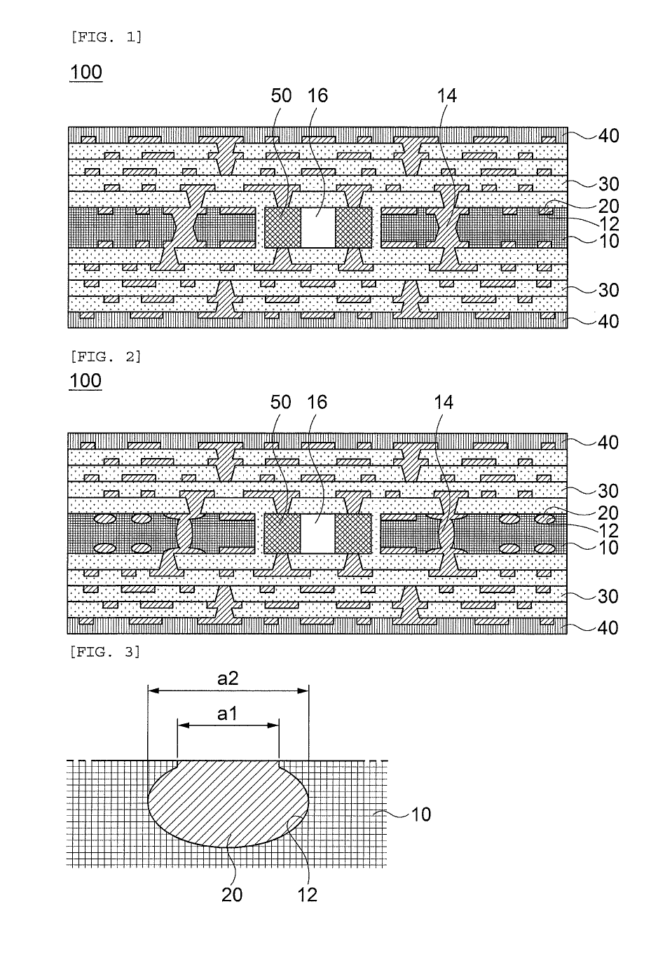

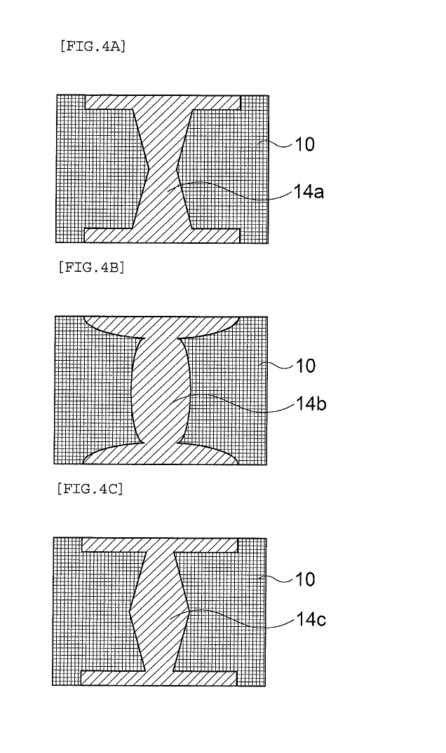

FIG. 1 is a cross-sectional view of a printed circuit board (PCB) including a glass core according to a first embodiment of the present invention. FIG. 2 is a cross-sectional view of a PCB including a glass core according to a second embodiment of the present invention. FIG. 3 is a partially enlarged view of a pattern part of FIG. 3. FIGS. 4A, 4B, and 4C are exemplary views of a through via of a PCB including a glass core according to an embodiment of the present invention.

As illustrated in FIGS. 1 to 4C, the PCB 100 including a glass core according to the embodiments of the present invention includes the glass core 10 in which pattern formation grooves 12 and through via holes 14 are formed, a plating layer 20 formed on the pattern formation grooves 12 and the through via holes 14, insulating layers 30 stacked on upper and lower surfaces of the glass core 10, and solder resist layers 40 formed on the insulating layers 30 via coating.

The glass core 10 has the thickest portion among all components of a build up PCB and thus may be prepared to a thickness of a minimum of 50 to 150 μm. Of course, the embodiments of the present invention are not limited this range, but this range refers to a minimum thickness range when an electronic device 50 is installed in the PCB.

In addition, a surface of the glass core 10 is smooth, and thus, surface roughness is formed on the surface of the glass core 10 so as to build up a layer thereon. Although not illustrated, the surface roughness may be formed to have 0.1 to 1 μm via a chemical method or a physical bombardment method such as sand brush.

The pattern formation grooves 12 for forming a pattern may be formed on opposite surfaces, that is, upper and lower surfaces of the glass core 10.

The pattern formation grooves 12 may have a rectangular shape. Thus, the pattern formation grooves 12 may have a longer horizontal length than a vertical length. In addition, the pattern formation grooves 12 may be processed by applying a laser beam to the glass core 10 may be formed by etching the glass core 10 via chemicals such as hydrofluoric acid that is mainly used to melt glass.

In addition, the pattern formation grooves 12 may be formed to have a circular or oval shape. That is, the pattern formation grooves 12 may be processed by adjusting an etching amount to acquire over-etching when patterns are formed via chemicals such as hydrofluoric acid.

When the pattern formation groove 12 is formed to have a circular or oval shape, an area ratio is increased compared with a case in which the pattern formation groove 12 have a square shape, thereby minimizing separation of the plating layer 20.

In other words, when the pattern formation groove 12 is formed to have a circular or oval shape, an inner diameter a2 of a central part is greater than an upper inner diameter a1, and thus, a higher area ratio may be obtained compared with an area ratio of a square shape having a constant inner diameter.

In this case, surface roughness may be formed on inner surfaces of the pattern formation grooves 12 so as to increase adhesion intensity with the plating layer 20.

The through via holes 14 are formed in the glass core 10. The through via holes 14 may have various shapes such as an hourglass type 14a, an oval type 14b, an inverse-hourglass type 14c, and the like.

The through via holes 14 may be process via etching or using a laser beam. The hourglass type 14a may be formed using a laser beam. The oval type 14b and the inverse-hourglass type 14c may be formed via etching using chemicals.

When the pattern formation grooves 12 and the through via holes 14 are formed in the glass core 10 using a laser beam or via etching, the plating layer 20 is formed via electroplating or electroless plating.

The plating layer 20 may be formed of a material with excellent conductivity such a copper (Cu) or gold (Au) and may maintain the same or lower level with respect to a surface of the glass core 10.

When the plating layer 20 is formed on the glass core 10, the insulating layers 30 including a plurality of layers are stacked on opposite surfaces of the glass core 10.

In addition, the solder resist layers 40 are formed on an uppermost layer and a lowermost layer of the insulating layer 30.

When the electronic device 50 is installed in the glass core 10, a cavity 16 for accommodation the electronic device 50 therein may be formed.

The cavity 16 may be formed to sufficiently install the electronic device 50 therein and may be formed through the glass core 10 in a vertical direction using a laser beam.

The cavity 16 may be formed through the glass core 10 according to the number of electronic devices 50 installed in the glass core 10. For example, the cavity 16 may be formed such that two or three electronic devices 50 may be accommodated in one cavity 16.

In the PCB 100 including a glass core according to the embodiments of the present invention, the electronic device 50 is installed in the cavity 16 when the pattern formation grooves 12 and through via holes 14 of the glass core 10 are formed and then the plating layer 20 is formed via a plating process.

When a plurality of layers is stacked on the glass core 10 accommodating the electronic device 50 therein, some resin of the insulating layer 30 is introduced between the electronic device 50 and the cavity 16 thereby preventing movement of the electronic device 50.

Then, a plurality of layer is sequentially formed and then the solder resist layers 40 are formed on an uppermost layer and a lowermost layer.

The glass core 10 on which a plurality of layers is built up may minimize warpage due to stacking the plural layers and warpage due to formation of the cavity via the glass core 10.

In addition, when patterns are formed on the glass core 10, the pattern formation grooves 12 may be formed rapidly using chemicals. After the pattern formation grooves 12 are formed in the plating layer 20, the plating layer 20 in a stable state may be formed due to a sufficient area ratio.

A PCB including a glass core according to the embodiments of the present invention may reduce warpage of a substrate due to use of the glass core to improve productivity and reliability.

In addition, according to the present invention, a total thickness of the PCB may be effectively reduced as patterns are formed in the glass core while providing excellent smoothness.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions, and substitutions should also be understood to fall within the scope of the present invention.

What is claimed is:

1. A printed circuit board (PCB),comprising:
a glass core having upper and lower surfaces in which pattern formation grooves and through via holes are formed;
a plating layer filled in the pattern formation groves and the through via holes;
insulating layers stacked on the upper and lower surfaces of the glass core; and
solder resist layers formed on the insulating layers via coating.

2. The PCB according to claim 1, wherein the pattern formation grooves are each formed to have a square shape.

3. The PCB according to claim 1, wherein the pattern formation grooves are each formed to have a circular or oval shape.

4. The PCB according to claim 1, wherein the pattern formation groove includes an inner diameter a2 of a central part, which is greater than an upper inner diameter a1.

5. The PCB according to claim 1, wherein the through via hole is formed to have any one of an hourglass type, an oval type, and an inverse-hourglass type.

6. The PCB according to claim 1, wherein the pattern formation groove has a greater horizontal width than a vertical width.

7. A printed circuit board (PCB),comprising:
a glass core including pattern formation grooves and through via holes and including a cavity for accommodating an electronic device therein;
a plating layer filled in the pattern formation grooves and the through via holes;
insulating layers stacked on the upper and lower surfaces of the glass core; and
a solder resist layer formed on the insulating layer via coating.

8. The PCB according to claim 7, wherein the pattern formation grooves are each formed to have a square shape.

9. The PCB according to claim 7, wherein the pattern formation grooves are each formed to have a circular or oval shape.

10. The PCB according to claim 7, wherein the through via hole is formed to have any one of an hourglass type, an over type, and an inverse-hourglass type.

11. The PCB according to claim 7, wherein the pattern formation groove includes an inner diameter of a central part, which is greater than an upper inner diameter.
